(19) United States
(12) Patent Application Publication
(10) Pub. No.: US 2008/0159339 A1
(43) Pub. Date: Jul. 3, 2008

(54) All-Solid State Uv Laser System

(75) Inventors: Ulrich Weichmann, Aachen (DE); Holger Moench, Vaals (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS, N.V., EINDHOVEN (NL)

(21) Appl. No.: 11/816,285

(22) PCT Filed: Feb. 7, 2006
(86) PCT No.: PCT/IB2006/050390

§ 371 Date: Aug. 15, 2007

(30) Foreign Application Priority Data
Feb. 17, 2005 (EP) 05101174.0

(51) Int. Cl. H01S 5/06

(52) U.S. Cl. 372/5

(57) ABSTRACT

The present invention relates to an all-solid state UV laser system comprising at least one semiconductor laser (10) in a VECSEL configuration. The gain structure (3) in this semiconductor laser (10) emits fundamental radiation in a wavelength range which can be frequency doubled to wavelengths in the UV region. The frequency doubling is achieved with a nonlinear optical crystal (6) for second harmonic generation arranged inside the extended cavity of the semiconductor laser (10). By electrically pumping of the semiconductor laser wavelengths below 200 nm can be efficiently generated with already known semiconductor materials like GaN. The proposed UV laser system is compact and can be fabricated and operated at low costs compared to UV excimer lasers.

The present invention relates to an all-solid-state UV laser system comprising at least one semiconductor laser in a VECSEL (Vertical Extended Cavity Surface Emitting Laser) configuration, said semiconductor laser having a gain structure arranged between a first mirror and an external mirror, said first and said external mirror forming a laser resonator of the semiconductor laser.

In many technical fields a strong demand for compact ultraviolet light sources exists. An exemplary application is microlithography in the deep ultraviolet wavelength region. In this application the most important light sources are excimer lasers. These laser sources are capable of generating a high average power output of coherent radiation, for example at wavelengths of 248, 193 and 157 nm. However, excimer lasers are rather involved setups with a bulky design, a limited efficiency and the requirement of continuous service. Typical tube lifetimes of excimer lasers used in lithography are about 500 hours under continuous operation, where the gas-mixtures have to be replaced every week. The poisonous nature of the excimer gases is a further reason for the strong demand for alternative light sources in microlithography applications.

Solid-state lasers would be a good alternative to gas-discharge lasers in microlithography. Up to now however there is no solid-sate gain medium that directly emits radiation at the required deep ultraviolet wavelengths. GaN laser-diodes provide the shortest wavelengths known today, with wavelengths in the range of 345 nm and above.

U.S. Pat. No. 6,693,941 describes a semiconductor laser system which generates laser radiation in the UV wavelength region. The semiconductor laser system comprises a surface emission type semiconductor laser in a VECSEL configuration which is based on a GaN type of semiconductor as the active layer. The surface emission type semiconductor laser is optically pumped by a GaN semiconductor laser as pumping beam source. The fundamental radiation in the range of 400 nm to 560 nm emitted from the active layer is frequency doubled in a nonlinear optical crystal arranged between the gain structure and the external mirror of the surface emission type semiconductor laser. Due to this frequency doubling the solid state laser system of this document is capable to produce ultraviolet radiation in the wavelength range between 200 and 280 nm. The use of a BBO as the nonlinear optical crystal limits this frequency range to frequencies of above 205 nm due to its limited phase-matching range.

In such an optically pumped semiconductor laser system the pump laser frequency must be lower than the fundamental radiation of the pumped gain medium. Due to the reduced efficiency of a GaN pump laser with lower wavelengths, e.g. of 375 nm, it is difficult to achieve UV laser radiation in the deep UV region below 200 nm in such a semiconductor laser system with a sufficient efficiency. Furthermore, the disclosed nonlinear BBO crystal does not allow the generation of such low wavelengths.

It is an object of the present invention to provide a compact UV laser system capable of generating UV radiation even below a wavelength of 200 nm with high efficiency.

This object is achieved with the all-solid state UV laser system according to claim 1. Advantageous enhancements of the invention are characterized in the dependent claims or pointed out in the following description and examples of the invention.

The proposed all-solid-state UV laser system comprises at least one semiconductor laser in a VECSEL (Vertical Extended Cavity Surface Emitting Laser) configuration. The semiconductor laser has a gain structure arranged between a first mirror and an external mirror, said first and said external mirror forming a laser resonator of the semiconductor laser. The gain structure comprises electrical contacts to be electrically pumped and emits fundamental radiation when electrically pumped, which allows the generation of UV radiation by frequency doubling. This gain medium is based on a semiconductor material like GaN, emitting radiation with a sufficiently high frequency. Said external mirror is highly reflective for this fundamental radiation and sufficiently transparent for said UV radiation formed by frequency doubling of the fundamental radiation. A solid state medium, preferably a non linear optical crystal, for generation of the second harmonic of said fundamental radiation is arranged in the laser resonator between the gain structure and said external mirror.

To avoid misunderstandings it is pointed out that in the context of the present description and claims the phrase “comprising” does not exclude further elements and that the phrases “a” and “an” do not exclude a plurality of the elements following these phrases. The reference signs used in the claims do only indicate exemplary embodiments but should not be understood to limit the scope of the claims.

The present UV laser system comprises an electrically pumped semiconductor laser in a VECSEL configuration. The fundamental radiation emitted by the gain structure is frequency doubled by intra-cavity second harmonic generation. The electrically pumped configuration allows the generation of UV radiation with wavelengths below 200 nm with a high efficiency. The semiconductor material for the gain structure and the solid state medium for frequency doubling can be optimally chosen for generating the desired radiation with wavelengths in the deep UV spectral region. By using e.g. a GaN based material as the semiconductor material and a KBBF crystal (KBBF: KBe₂BO₃F₂) as the medium for second harmonic generation UV radiation down to 177 nm can be generated with a high efficiency. Instead of KBBF also a SBBO crystal (SBBO: Sr₂Be₂B₂O₇) can be used as a nonlinear optical crystal in the present UV laser system. The present laser system furthermore is more compact and can be fabricated with lower costs than and optically pumped semiconductor laser.

Since in several applications of UV laser systems a high beam quality is not of importance, an advancement of the present UV laser system comprises several of said semiconductor lasers, which are arranged to form an array of laser sources. In this advancement the semiconductor lasers are preferably adapted to emit UV radiation of a wavelength of 193 nm. With this emission wavelength the present UV laser system can be used to replace ArF excimer lasers, in particular in the field of microlithography. Due to the arrangement of the semiconductor lasers in form of an array, this laser system provides enough power to replace excimer laser sources.

A preferred field of application of the present all-solid-state UV laser system is the field of photolithography or microlithography in the deep ultraviolet spectral region. The use of the present UV laser system however is not restricted to the above field. The laser system can be applied in all fields in which UV laser sources are needed, for example in the field of biomedical diagnostics, in biomolecular applications, e.g. in diagnostics, treatment or production of substances, especially genomic materials, in the field of material treatment in general or especially for the treatment of air, water and tissue with medical or disinfection proposes.

These and other aspects of the invention will be apparent from and elucidated with reference to the embodiments and accompanying figures described herein after. The figures show:

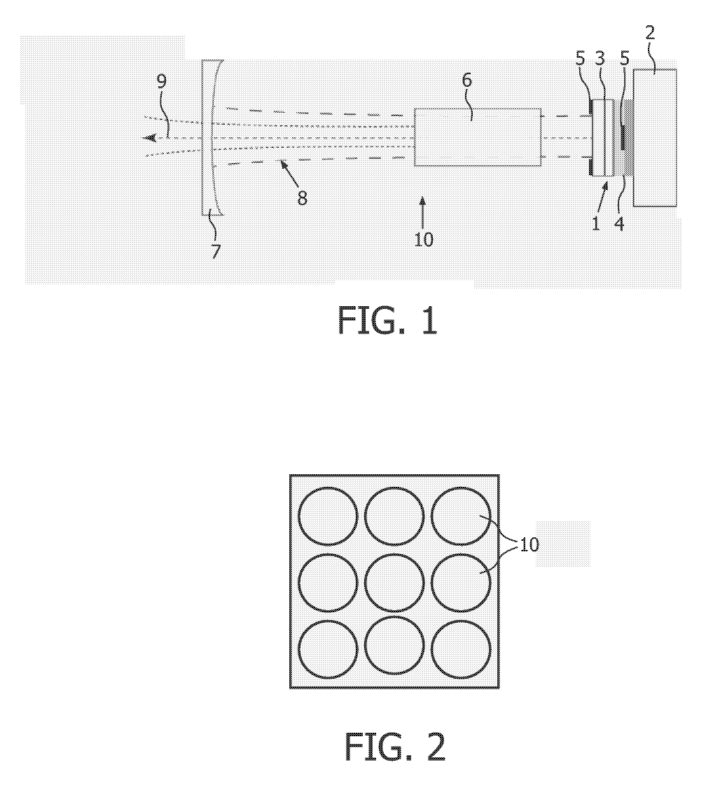

FIG. 1 an example for a configuration of a UV laser system according to the present invention; and

FIG. 2 schematically a UV laser system according to the present invention formed by an array of semiconductor lasers.

The semiconductor laser of the present UV laser system is based on intra-cavity second harmonic generation of a GaN based semiconductor laser in a vertical external cavity set up. This VECSEL configuration including the nonlinear optical crystal for second harmonic generation is depicted schematically in FIG. 1. In this example one part of the laser resonator is formed by a GaN based laser diode 1 including a distributed Bragg reflector (DBR) resonator mirror together with the GaN gain structure 3. The gain structure 3 comprises front and back electrical contacts 5 for electrically pumping of the gain structure 3. The laser diode 1 is mounted on a heat sink 2. The detailed layout of such a GaN based laser diode is known in the art so that this layout is not explained in detail in this description. In the present UV laser system any kind of surface emitting laser diode with a proper gain medium for the intended wavelength of fundamental radiation is suitable. Furthermore, it is also possible to use other types of resonator mirrors, for example a distributed feedback (DFB) structure, in this laser diode.

In the present example the GaN based VECSEL diode emits a fundamental radiation 8 of 386 nm when electrically pumped. The external resonator mirror 7 which is mounted distant from the GaN based laser diode 1 forms the laser resonator together with the DBR-mirror 4 that is grown on the gain structure 3 of the laser diode 1. This external resonator mirror 7 is highly reflective for the fundamental wavelength and transparent for the second harmonic radiation. The transparency for this second harmonic radiation must not be 100% but sufficient for coupling out a large portion of this UV radiation. The second harmonic radiation 9, in the present case with a wavelength of 193 nm, is generated from the fundamental radiation in the nonlinear optical crystal 6 that is placed inside the extended laser cavity, i.e. between the laser diode 1 and the external mirror 7. In the present example this nonlinear optical crystal 6 is a KBBF crystal which can be mounted in a prism coupling technique in the extended laser cavity. In such a prism coupling technique the fundamental radiation is coupled through prisms in and out of the crystal which are fixed to both sides of the crystal.

Since the wavelength of the fundamental radiation of GaN based laser diodes is controlled by the layer structure and doping of the gain medium, also other UV wavelengths can be generated by varying the above parameters in the fabrication of the gain structure.

Depending on the electrical pumping such a UV laser system can be operated in continuous wave or in pulsed mode. Furthermore, the present UV laser system is not limited to one single semiconductor laser. FIG. 2 shows schematically an example of an UV laser system which comprises several of the semiconductor lasers 10 of FIG. 1 arranged to form an array of laser sources. FIG. 2 shows a view of such an array in the opposite direction of the emitted UV laser beams.

With the all-solid-state UV laser system of the present invention current light sources for microlithography, in particular bulky excimer lasers can be replaced. Nevertheless the present all-solid-state UV laser system can also be used in many other applications sharing the need for a compact low cost UV laser source for the deep UV wavelength region.

### LIST OF REFERENCE SIGNS

1 GaN based VECSEL diode
2 heat sink
3 GaN based gain structure
4 DBR-mirror
5 electrical contacts
6 nonlinear optical crystal
7 external mirror
8 fundamental radiation
9 second harmonic radiation
10 semiconductor laser

### LIST OF ABBREVIATIONS

VECEL=vertical extended cavity surface emitting laser
BBO=(β-BaB₂O₄)
KBBF=KBe₂BO₃F₂
SBBO=Sr₂Be₂B₂07
DBR=Braggreflector

1. All-solid-state UV laser system comprising at least one semiconductor laser (10) in a VECSEL configuration, said semiconductor laser (10) having a gain structure (3) arranged between a first mirror (4) and an external mirror (7), said first (4) and said external mirror (7) forming a laser resonator of the semiconductor laser (10),
wherein said gain structure (3) comprises electrical contacts (5) to be electrically pumped and emits a fundamental radiation (8) when electrically pumped, which allows the generation of UV-radiation (9) by frequency doubling,
wherein said external mirror (7) is highly reflective for the fundamental radiation (8) and transparent for said UV-radiation (9), and
wherein a solid state medium (6) for generation of a second harmonic of said fundamental radiation (8) is arranged in the laser resonator between said gain structure (3) and said external mirror (7).

2. All-solid-state UV laser system according to claim 1,
characterized in that said gain structure (3) and said solid state medium (6) for second harmonic generation are adapted to generate second harmonic radiation in the wavelength range between 170 and 220 nm.

3. All-solid-state UV laser system according to claim 1,
characterized in that said solid state gain structure (3) is a GaN based structure.

4. All-solid-state UV laser system according to claim 1,
characterized in that said solid state medium for second harmonic generation is a KBBF crystal.

5. All-solid-state UV laser system according to claim 1,
characterized in that said solid state medium for second harmonic generation is a SBBO crystal.

6. All-solid-state UV laser system according to claim 1,
characterized in that said first mirror (4) is formed of a DBR-structure grown on said gain structure (3).

7. All-solid-state UV laser system according to claim 1,
characterized in that several of said semiconductor lasers (10) are arranged to form an array of laser sources.

8. The use of an all-solid-state UV laser system according to claim 1 in the field of microlithography.

9. The use of an all-solid-state UV laser system according to claim 1 for biomolecular or biomedical applications.
